(19) United States
(12) Patent Application Publication
(10) Pub. No.: US 2009/0325328 A1
(43) Pub. Date: Dec. 31, 2009

(54) Plasma processing apparatus and plasma processing method

(75) Inventors: Seiji Samukawa, Sendai-shi (JP); Satoshi Nishikawa, Tokyo (JP); Shingo Kadomura, Yokohama-shi (JP)

Correspondence Address: STAAS & HALSEY LLP, SUITE 700, 1201 NEW YORK AVENUE, N.W., WASHINGTON, DC, 20005, US

(73) Assignee: SEMICONDUCTOR TECHNOLOGY ACADEMIC RESEARCH CENTER, Kanagawa (JP)

(21) Appl. No.: 12/585,119

(22) Filed: Sep. 3, 2009

Related U.S. Application Data
(62) Division of application No. 11/060,598, filed on Feb. 18, 2005.

(30) Foreign Application Priority Data
May 28, 2004 (JP) 2004-159531

(51) Int. Cl. H01L 21/66

(52) U.S. Cl. 438/17; 257/E21.215; 257/E21.529

(57) ABSTRACT

A plasma processing method is provided. The method includes providing photon detection sensors for measuring an ultraviolet-light-induced current around circumferential portions of a wafer stage within a plasma chamber. The method also includes providing a semiconductor wafer on the wafer stage and performing plasma processing so as to form an insulating layer the semiconductor wafer or etch an insulating layer formed on the semiconductor wafer.

### CROSS-REFERENCE TO RELATED APPLICATION(S)

This application is related to and is a Divisional Application of to U.S. application Ser. No. 11/060,598 filed on Feb. 18, 2005 now pending and claims priority to Japanese Patent Application No. 2004-159531, filed on May 28, 2004, and incorporated by reference herein.

### BACKGROUND

1. Field

The embodiments discussed herein are directed to a plasma processing apparatus, and to a plasma processing method, for processing a semiconductor wafer or the like and, more particularly, to a plasma processing apparatus and to a plasma processing method capable of monitoring, in real time, an abnormal discharge phenomenon that can occur during plasma processing.

2. Description of the Related Art

Plasma processes such as etching, thin-film deposition, etc. are indispensable for, achieving high-quality, high-functionality semiconductor devices. However, one problem involved with such plasma processes is that an abnormal discharge can occur abruptly during processing in a plasma processing apparatus. If an abnormal discharge occurs, etching and thin-film deposition conditions change and, as a result, the characteristics of the produced semiconductor device substantially change. In the worst case, the processing apparatus may be damaged. Accordingly, in order to produce high-reliability semiconductor devices while ensuring high productivity, it is essential to monitor the occurrence of an abnormal discharge, in real time, during plasma processing and to take quick and appropriate action to deal with the abnormality.

An abnormal discharge occurs when the large electric charge accumulated on the inside wall of the plasma chamber, etc. either exceeds a limit or is discharged for some reason during plasma processing. As such discharge occurs in an unpredictable manner, and as there are no effective sensing methods for detecting the occurrence, with a prior known plasma processing apparatus, it has not been possible to take appropriate action by detecting the occurrence of such an abnormal discharge in real time, and this has led to the degradation of the productivity, as well as the reliability, of the produced semiconductor device.

An on-wafer monitoring system has already been proposed that measures the plasma processing state by a sensor build into a semiconductor wafer (Japanese Unexamined Patent Publication 2003-282546). This system is one that monitors the energy distribution, ion current, etc., for example, of the ions, electrons, and other particles generated by the plasma, but, as these changes manifest themselves relatively slowly on the semiconductor wafer in contrast with an instantaneous change in the plasma state such as an abnormal discharge, the proposed system is not suitable for real-time monitoring of an abnormal discharge.

### SUMMARY

It is an aspect of the embodiments discussed herein to provide a plasma processing apparatus and plasma processing method that can monitor the plasma state in real time during processing and, more particularly, can monitor in real time the occurrence of an abnormal discharge.

The above aspects can be attained by a plasma processing apparatus including a chamber equipped with a wafer stage for mounting thereon a substrate, for example, a semiconductor wafer, to be processed, and which processes the substrate by exposure to a plasma, a photon detection sensor for measuring an ultraviolet-light-induced current is placed on a circumferential portion of a substrate mounting surface of the wafer stage.

The photon detection sensor includes a semiconductor substrate, an insulating film formed over the semiconductor substrate, an electrode layer embedded in the insulating film, a means for applying a bias voltage to the electrode layer, and a means for detecting a current flowing in the electrode layer.

When an abnormal discharge occurs in the plasma chamber, the plasma density appreciably drops at that instant because of the discharge, and the generation of ions, neutral particles, electrons, and ultraviolet light by the plasma decreases. When the photon detection sensor is installed, during the generation of the plasma a certain amount of current induced by the ultraviolet light generated from the plasma is observed in a steady-state condition; however, when the plasma density drops due to an abnormal discharge, and the amount of ultraviolet light generation decreases, then a spike-like current drop is observed. Accordingly, by installing the photon detection sensor on the wafer stage in the plasma processing apparatus, and by monitoring the sensor output in real time, the occurrence of an abnormal discharge manifesting itself as a spike-like current drop can be detected in real time. As a result, quick and appropriate action can be taken to deal with the abnormal discharge.

The photon detection sensor further includes a second electrode formed on the insulating film. With the provision of this electrode, the influence of only the ultraviolet light can be observed by eliminating the influence of particles other than the vacuum ultraviolet light, such as ions and electrons. This serves to enhance the accuracy in detecting the occurrence of an abnormal discharge.

Further, a plurality of sensors, each identical to the above-described photon detection sensor, are arranged spaced apart from each other on the wafer stage. With this arrangement, it becomes possible to know the spatial distribution indicating the extent to which the effect of the abnormal discharge has spread, thus making it easier to determine, for example, which devices on the semiconductor wafer are affected.

The above aspects can also be attained by a plasma processing method including placing a plurality of photon detection sensors, each for measuring an ultraviolet-light-induced current, on a wafer stage provided within a plasma chamber; placing the substrate to be processed on the wafer stage; performing plasma processing in the plasma chamber in which the photon detection sensors and the substrate to be processed are placed; and monitoring an output current from each of the photon detection sensors while the plasma processing is being performed.

The plasma processing method further includes that when a spike-like current drop different from a steady-state current is observed in the monitoring of the photon detection sensors, the spike-like current drop is recognized as indicating the occurrence of an abnormal discharge.

According to the above method, the current induced by the ultraviolet light generated from the plasma is detected by the photon detection sensor mounted on the wafer stage while the plasma processing of the substrate is being performed; in this way, any abnormal discharge occurring in the plasma chamber can be detected in real time in the form of a change in current value. Accordingly, quick action can be taken to deal with the abnormality, offering the effect of enhancing the reliability and productivity of semiconductor devices. These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a diagram showing in simplified form the configuration of a plasma processing apparatus according to one embodiment;

FIG. 2 is a plan view of a wafer stage in the plasma processing apparatus shown in FIG. 1;

FIG. 3 is a diagram showing an exemplary result of a measurement of an electric current value of a photon detection sensor;

FIG. 4 is a diagram showing a first embodiment of the photon detection sensor used in the plasma processing apparatus of the present invention;

FIG. 5A is a diagram for explaining a fabrication operation for the photon detection sensor shown in FIG. 4;

FIG. 5B is a diagram for explaining another fabrication operation for the photon detection sensor shown in FIG. 4;

FIG. 5C is a diagram for explaining a further fabrication operation for the photon detection sensor shown in FIG. 4;

FIG. 5D is a diagram for explaining a still further fabrication operation for the photon detection sensor shown in FIG. 4;

FIG. 6A is a cross-sectional view in one fabrication operation for the photon detection sensor shown in FIG. 4;

FIG. 6B is a plan view of the photon detection sensor shown in FIG. 6A; and

FIG. 7 is a diagram showing a second embodiment of the photon detection sensor used in the plasma processing apparatus of the present invention.

### DETAILED DESCRIPTION OF THE PREFERRED EMBODIMENTS

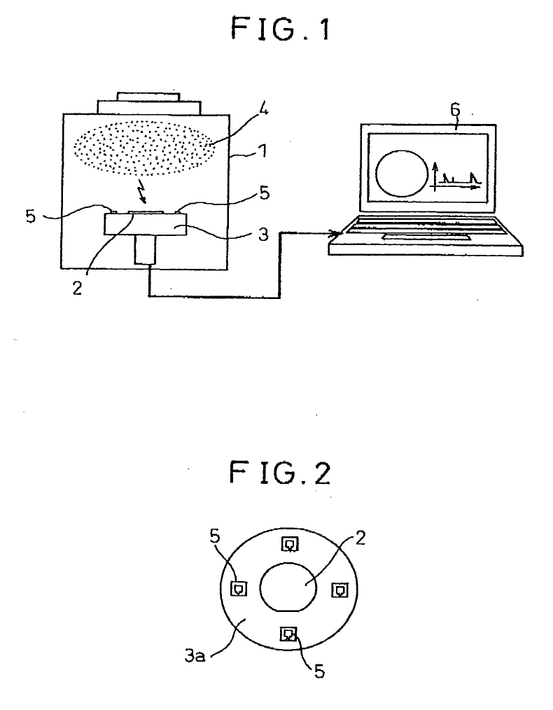

FIG. 1 is a diagram showing, in simplified form, the configuration of a plasma processing apparatus according to an exemplary embodiment. Reference numeral 1 is a chamber for performing a plasma process therein; the chamber 1 is equipped with a wafer stage 3 for mounting thereon a substrate to be processed, i.e., a semiconductor wafer 2. A gas excited into a plasma state (hereinafter simply referred to as the plasma) 4 is introduced into the chamber 1, and a plasma process such as etching or thin-film deposition is performed on the semiconductor wafer 2. The plasma 4 can also be formed within the chamber 1 by applying high-frequency energy from outside the chamber to a gas introduced into the chamber 1. Usually, an insulating film for preventing the discharge of the plasma 4 is formed on the inside wall of the chamber 1.

FIG. 2 is a plan view of the wafer stage 3. As shown, one or more photon detection sensors 5 are arranged on the surface 3a of the wafer stage 3 on which the semiconductor wafer 2 is to be mounted. The structure of the photon detection sensor and its sensor mechanism will be described later. As shown, the photon detection sensors 5 are arranged at equally spaced intervals around the circumferential portion of the surface 3a of the wafer stage 3. A data processing apparatus 6, which performs data processing by detecting a change in an electric current being output from each photon detection sensor 5, is connected to the photon detection sensors 5.

The plasma processing apparatus shown in FIG. 1 detects a change in the electric current value of each of the plurality of photon detection sensors 5 while performing processing of the semiconductor wafer 2 by exposing it to the plasma. The present inventor has discovered that when an abnormal discharge occurs within the chamber 1, the output, i.e., the electric current value, of the photon detection sensor 5 drops in a spike-like manner. Accordingly, by observing the output of each photon detection sensor 5 during the processing of the semiconductor wafer 2, any abnormal discharge occurring in the chamber 1 can be detected. Further, by simultaneously monitoring the outputs of the plurality of photon detection sensors 5, it becomes possible to detect the spatial distribution of the abnormal discharge, which shows which portions of the semiconductor wafer 2 are affected by the abnormal discharge.

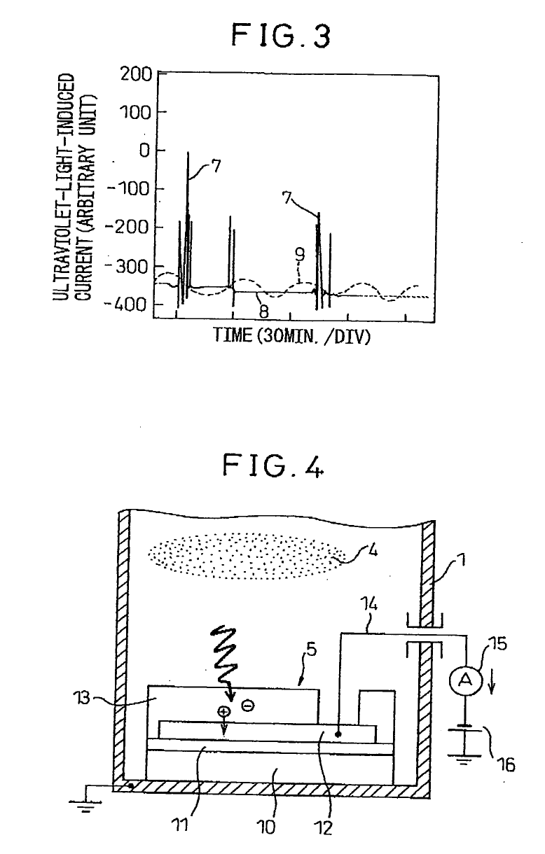

FIG. 3 shows one example of how the output of the photon detection sensor 5 changes. In the figure, the ordinate represents the ultraviolet-light-induced current value of the photon detection sensor 5 measured in arbitrarily chosen units, and the abscissa represents the time. In the photon detection sensor 5, a current 8 induced by the ultraviolet light generated from the plasma is constantly observed in accordance with a mechanism to be described later and, during that process, a spike-like drop 7 in the electric current value is observed. The present inventor has discovered that the spike-like drop 7 is caused by an abnormal discharge occurring in the chamber 1.

Accordingly, the time of occurrence, the magnitude, and the spatial distribution of the abnormal discharge in the chamber 1 can be deduced from the detected occurrence of the drop 7, its magnitude, and the position on the wafer stage 3 of the photon detection sensor 5 whose output exhibited the drop.

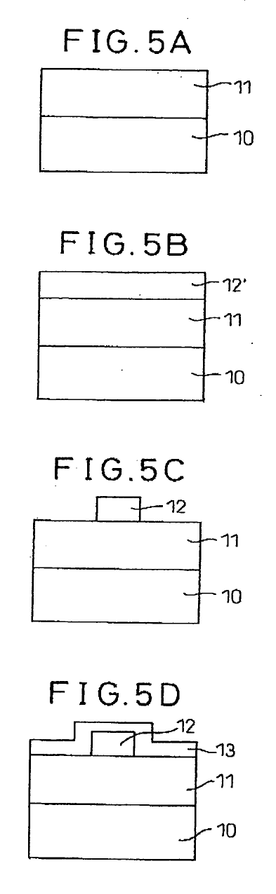

Next, the structure of the photon detection sensor 5 used in the present invention, its operating principle, and the mechanism by which an abnormal discharge is detected using the photon detection sensor will be described with reference to FIGS. 4 and 5.

FIG. 4 shows a first embodiment of the photon detection sensor 5. In FIG. 4, for convenience of explanation, the photon detection sensor 5 is shown as being mounted directly on the bottom of the chamber, but in practice, the sensor is mounted on the wafer stage 3 on which the semiconductor wafer is to be held, as shown in FIG. 1. In the figures hereinafter given, the same reference numerals as those in FIGS. 1 and 2 designate the same or similar component elements, and the description of such elements will not be repeated here.

In the photon detection sensor 5 shown in FIG. 4, reference numeral 10 is a Si semiconductor substrate, 11 is a first insulating film formed from SiO₂ or the like, 12 is an electrode formed from Al, and 13 is a second insulating film formed from SiO₂ or the like. A portion of the second insulating film 13 is removed by suitable means such as etching to expose a portion of the electrode 12. A wiring line 14 is connected to the exposed portion, and the current flowing in the electrode 12 is measured by an ammeter 15. Reference numeral 16 is a power supply for applying a bias voltage to the electrode 12.

Ions, neutral particles, electrons, and ultraviolet light are generated in the plasma. In this ultraviolet radiation, there is radiation that has large energy and cannot pass through the insulating films 12 and 13. Such ultraviolet radiation is absorbed by the insulating films 12 and 13 and forms electron-hole pairs in the films. The holes, whose mobility is lower than the electrons, are trapped by defects formed in the insulating films 12 and 13, and thus form positive fixed charges. Here, when a bias voltage is applied to the electrode 12, these charges can be detected as a hole current by the ammeter 15.

At the interface between the Si semiconductor substrate and the insulating film, for example, the SiO₂/Si interface, there exist many defects formed by so-called dangling bonds of Si. The holes formed in the SiO₂ film by absorbing high-energy light such as vacuum ultraviolet light are trapped by such defects formed at the SiO₂/Si interface, and thus form positive fixed charges. Accordingly, the electric current value measured by the ammeter 15 during plasma processing has correlation with the amount of fixed charge at the SiO₂/Si interface.

It is presumed that the steady-state current value 8 shown in FIG. 3 has a relationship with the current generated based on the positive fixed charges. In a MOS transistor or the like, the number of positive fixed charges greatly affects the device characteristics. Accordingly, the characteristics of the semiconductor device being produced can be predicted to a certain extent from the measured electric current value.

It is known that the energy of the plasma 4 fluctuates in cyclic fashion based on its generation process. This fluctuation of the plasma is observed as a fluctuation in the steady-state current value, as shown by reference numeral 9 in FIG. 3, when measuring the electric current value of the photon detection sensor 5. Accordingly, by detecting the fluctuation of the electric current value of the sensor 5, the fluctuation of the plasma can be observed, which has not been possible with the prior art.

Usually, the inside surface of the plasma chamber 1 is treated with an insulating film to prevent contact with the high-energy plasma 4 and thereby prevent discharge of the plasma energy. Accordingly, as the plasma process progresses, a large electric charge is accumulated on the insulating film. When the charge accumulation exceeds a limit, or when the accumulated charge is discharged for some reason, an abnormal discharge occurs in the chamber 1.

When an abnormal discharge occurs, the energy of the plasma 4 is released, and the plasma density thus drops. As a result, the ultraviolet light generated by the plasma 4 substantially decreases, and the number of electron-hole pairs to be formed in the insulating layers 12 and 13 substantially decreases in a corresponding manner. This decrease is observed by the ammeter 15 as a spike-like drop in the current value, as shown in FIG. 3.

Therefore, when a spike-like drop is detected in the current value, it can be determined that an abnormal discharge has occurred in the chamber 1. Here, when an abnormal discharge occurs, the density of the plasma 4 appreciably drops at that instant, and this greatly affects the plasma process in progress such as insulating film etching or thin-film deposition. This can significantly degrade or damage the characteristics of the semiconductor device being produced. Therefore, in order to improve the reliability and productivity of semiconductor devices, it is extremely important to detect the occurrence of an abnormal discharge during plasma processing, the magnitude of the abnormal discharge, and the spatial distribution of the abnormal discharge that occurred.

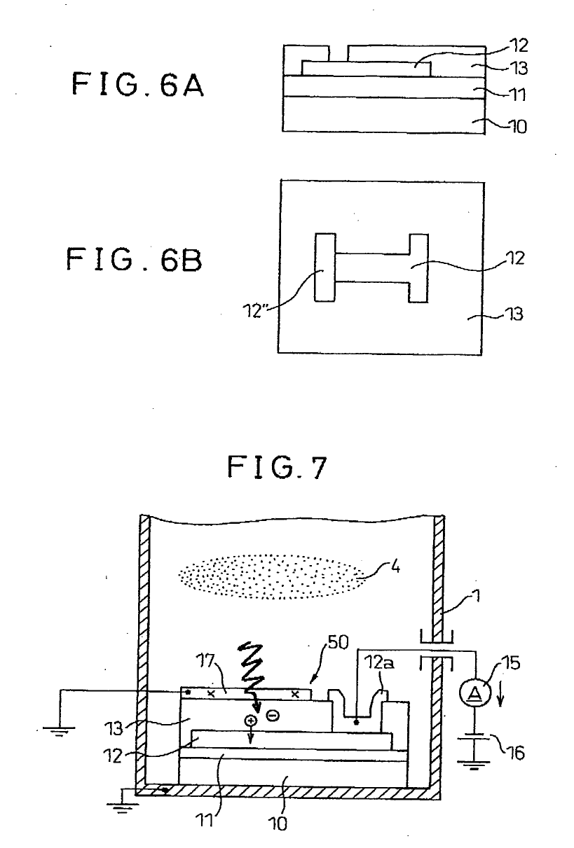

FIGS. 5 and 6 are diagrams showing a fabrication process for the ultraviolet-light-induced current measuring photon detection sensor 5 having the structure shown in FIG. 4. As shown in FIG. 5A, first the Si substrate 10 is subjected to wet thermal oxidation for 30 minutes at 1000° C., to form the SiO₂ film 11. The thickness of the film 11 is 3 μm. Next, as shown in FIG. 5B, Al as the electrode material is deposited (Al film thickness of 100 nm) to form an electrode layer 12′. Then, the electrode layer 12′ is etched by phosphoric acid (H₃PO₄), to form the electrode 12 of the desired shape as shown in FIG. 5C.

Next, plasma TEOS (tetraethoxysilane, Si(OC₂H₅)₄) is deposited to a thickness of 200 nm to form the oxide film 13, as shown in FIG. 5D, after which a portion of the oxide film 13 is etched off by hydrofluoric acid (HF:H₂O=1:50) to expose a portion 12″ of the electrode 12, as shown in FIG. 6A. Finally, a current measuring lead wire (not shown) is connected to the exposed portion 12″ of the electrode 12. After the lead wire is connected, the device is covered with an insulating film (not shown) to prevent charged particles from entering the device through the periphery of the lead wire.

FIG. 6B is a plan view showing the device shown in FIG. 6A as viewed from the top; here, the electrode 12 is shown through the overlying SiO₂ film 13, with the portion 12″ of the electrode exposed through the opening formed in the SiO₂ film 13.

When the photon detection sensor 5 is formed as described above, the sensor is mounted on the wafer stage 3 in the plasma chamber 1, and connected to the power supply 16 and the ammeter 15 outside the chamber 1 via a current lead terminal (not shown) connected to the electrode 12, and the ammeter 15 measures the electric current value when a bias voltage of 0 to 30 V is applied from the power supply 16. The electric current value when the plasma is not applied is about 10 to 20 pA, which means that virtually no current is flowing. The measured sensor output is processed by the data processing apparatus 6 and monitored by the user.

FIG. 7 is a diagram showing a second embodiment of the photon detection sensor used in the plasma processing apparatus of the present invention. The photon detection sensor 50 of this embodiment differs from the photon detection sensor 5 of the structure shown in FIG. 4 in that the SiO₂ film 13 is covered with an Al film 17 about 100 nm in thickness. Reference numeral 12a indicates the lead terminal of the electrode 12.

Ions, neutral particles, electrons, and ultraviolet light are generated in the plasma. Therefore, in the photon detection sensor 5 of FIG. 4, the SiO₂ film 13 is affected by charged particles such as ions and electrons, causing a variation in the measured current value. In the photon detection sensor 50 shown in FIG. 7, the film 13 is covered with the Al thin film 17 to prevent such particles from penetrating into the film 13. It is known that ultraviolet light with wavelengths of about 17 nm to 90 nm passes through the Al film. Therefore, by depositing the Al film 17 over the SiO₂ film 13, the influence only of vacuum ultraviolet light of 90 nm and shorter wavelengths that pass through can be observed by eliminating the influence of ions and electrons. The Al film 17 is grounded during plasma exposure.

In the photon detection sensors 5 and 50 described with reference to FIGS. 4 and 7, the insulating film has been formed from SiO₂, but the present invention is not limited to this particular material; for example, the insulating film can be equally achieved by using, for example, a nitride film or the like. The insulating film need only be formed using the same material as the insulating film formed on the semiconductor wafer or to be formed thereon and processed by etching.

As described above with reference to the various embodiments, in the plasma processing apparatus of the present invention, with the ultraviolet-light-induced current measuring photon detection sensor mounted on the wafer stage, any abnormal discharge phenomenon occurring in the plasma chamber can be detected in real time during the processing of the semiconductor wafer. Accordingly, when an abnormal discharge occurs, corrective action can be taken quickly, and as a result, semiconductor devices having high reliability can be produced while ensuring high productivity. Further, by arranging a plurality of photon detection sensors on the wafer stage, it becomes possible to know the spatial distribution of the abnormal discharge, so that more appropriate action can be taken to deal with the abnormal discharge.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A plasma processing method for processing a semiconductor wafer, comprising:
providing a plurality of photon detection sensors, each for measuring an ultraviolet-light-induced current, around circumferential portions of a wafer stage provided within a plasma chamber;
providing said semiconductor wafer on said wafer stage;
performing plasma processing in said plasma chamber, in which said photon detection sensors and said semiconductor wafer are placed, so as to form an insulating layer on said semiconductor wafer or etch an insulating layer formed on said semiconductor wafer; and
monitoring an output current from each of said photon detection sensors while said plasma processing is being performed,
wherein each of said photon detection sensors comprises a semiconductor substrate, an insulating film formed on said semiconductor substrate, an electrode layer embedded in said insulating film, means for applying a bias voltage to said electrode layer, and means for detecting a current flowing in said electrode layer, and
wherein said insulating film formed on said semiconductor substrate is chosen to be a same material as that of said insulating layer formed or to be formed on said semiconductor wafer.

2. A plasma processing method as claimed in claim 1, wherein when a spike-like current drop different from a steady-state current is observed during the monitoring of said photon detection sensors, said spike-like current drop is recognized as indicating the occurrence of an abnormal discharge in said plasma chamber.

3. A method for processing a semiconductor wafer, comprising:
measuring an ultraviolet-light-induced current around circumferential portions of a wafer stage provided within a plasma chamber with a plurality of photon detection sensors;
providing a semiconductor wafer on a wafer stage;
forming an insulating layer on the semiconductor wafer or etching an insulating layer formed on the semiconductor wafer; and
monitoring an output current from each of a plurality of photon detection sensors,
wherein each of the photon detection sensors comprises a semiconductor substrate with an insulating film chosen to be a same material as the insulating layer formed, or to be formed, on the semiconductor wafer, an electrode layer embedded in the insulating film, means for applying a bias voltage to the electrode layer, and means for detecting a current flowing in the electrode layer.

4. A plasma processing method as claimed in claim 3, wherein the monitoring further comprising recognizing a spike-like current drop indicates an occurrence of an abnormal discharge in the plasma chamber.
